(19) United States
(12) Patent Application Publication
(10) Pub. No.: US 2019/0296755 A1
(43) Pub. Date: Sep. 26, 2019

(54) CIRCULAR HISTOGRAM NOISE FIGURE FOR NOISE ESTIMATION AND ADJUSTMENT

(71) Applicant: QUALCOMM Incorporated, San Diego, CA (US)

(72) Inventors: Seyed Arash MIRHAJ, San Diego, CA (US); Masoud ENSAFDARAN, San Diego, CA (US); Lei SUN, San Diego, CA (US); Dinesh ALLADI, San Diego, CA (US)

(21) Appl. No.: 15/936,015

(22) Filed: Mar. 26, 2018

(51) Int. Cl. H03M 1/08; H03M 1/00

(52) U.S. Cl. CPC H03M 1/08; H03M 1/001; H03M 1/002

(57) ABSTRACT

Certain aspects of the present disclosure provide methods and apparatus for performing background noise estimation using a circular histogram noise figure (CHNF) in an analog-to-digital converter (ADC) circuit with redundancy. The estimated noise may be used to reduce the noise (e.g., comparator noise) in the ADC circuit. One example ADC circuit generally includes at least one of a comparator or a digital-to-analog converter (DAC) and at least one digital feedback input. The at least one digital feedback input is coupled to the at least one of the comparator or the DAC and is configured to adjust at least one parameter of the at least one of the comparator or the DAC based on at least a portion of an output of the ADC circuit.

### TECHNICAL FIELD

Certain aspects of the present disclosure generally relate to electronic circuits and, more particularly, to analog-to-digital converters (ADCs) with redundancy.

### BACKGROUND

An analog-to-digital converter (ADC) is an electronic circuit used to convert an analog signal to a digital signal, typically for performing signal processing in the digital domain. Several types of ADCs are available, each with varying advantages and disadvantages. For example, a successive approximation register (SAR) ADC may provide an area and power-efficient architecture for low-to-medium accuracy analog-to-digital conversion applications. A SAR ADC may use a digital-to-analog converter (DAC) and a comparator to approximate a digital value corresponding to an analog input. Another type of ADC referred to as a flash ADC may provide a faster conversion speed at the cost of an exponential increase in power and area consumption.

### SUMMARY

Certain aspects of the present disclosure generally relate to performing background noise estimation using a circular histogram noise figure (CHNF) in an analog-to-digital converter (ADC) circuit with redundancy. The estimated noise may be used to adjust the noise in the ADC circuit.

Certain aspects of the present disclosure provide an ADC circuit. The ADC circuit generally includes at least one of a comparator or a digital-to-analog converter (DAC) and at least one digital feedback input. The at least one digital feedback input is coupled to the at least one of the comparator or the DAC and is configured to adjust at least one parameter of the at least one of the comparator or the DAC based on at least a portion of an output of the ADC circuit.

Certain aspects of the present disclosure provide a method for operating an ADC circuit. The method generally includes processing an output of the ADC circuit, the ADC circuit comprising at least one of a comparator or a digital-to-analog converter (DAC), and adjusting at least one parameter of the at least one of the comparator or the DAC, based on at least a portion of the output of the ADC circuit.

Certain aspects of the present disclosure provide a method for operating an ADC circuit. The method generally includes generating a histogram of a residue of the ADC circuit, circularly shifting the histogram of the residue to generate a circularly shifted histogram, multiplying the circularly shifted histogram by the histogram of the residue, determining noise in the ADC circuit based on the multiplied histograms, and controlling a component of the ADC circuit based on the determined noise.

Certain aspects of the present disclosure provide an apparatus for converting an analog signal to a digital signal. The apparatus generally includes at least one of a comparator or a DAC; and means for adjusting at least one parameter of the at least one of the comparator or the DAC, based on at least a portion of an output of the apparatus.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a block diagram of an example analog-to-digital converter (ADC) circuit with redundancy, in accordance with certain aspects of the present disclosure.

FIG. 2A illustrates an example probability density function (PDF) of an analog residue at the last stage of an ideal multi-stage ADC with redundancy, in accordance with certain aspects of the present disclosure.

FIG. 2B illustrates an example PDF of a digital residue at any stage of an ideal multi-stage ADC with redundancy, in accordance with certain aspects of the present disclosure.

FIG. 3A is an example histogram illustrating non-linearity in the ADC circuit deforming the ideal histogram block shape of FIG. 2B without spreading over more histogram bins, in accordance with certain aspects of the present disclosure.

FIG. 3B illustrates how noise spreads the residue in the histogram of FIG. 3A over more histogram bins, in accordance with certain aspects of the present disclosure.

FIG. 4 is a flow diagram of example operations for running an ADC circuit, based on background noise estimation using a circular histogram noise figure (CHNF), in accordance with certain aspects of the present disclosure.

FIGS. 5A-5C illustrate determining noise in an ADC circuit based on a circularly shifted histogram of a residue of the ADC circuit, in accordance with certain aspects of the present disclosure.

FIGS. 6A-6C illustrate determining noise in an ADC circuit based on a circularly shifted histogram of a residue of the ADC circuit, with higher noise than illustrated in FIGS. 5A-5C, in accordance with certain aspects of the present disclosure.

FIG. 7 is a block diagram of an example ADC circuit and digital circuitry supporting background noise estimation and control feedback for adjusting noise of various components in the ADC circuit, in accordance with certain aspects of the present disclosure.

FIG. 8 is a table comparing example comparator types with various ADC circuit parameters that may be controlled to adjust noise of the ADC circuit of FIG. 7, in accordance with certain aspects of the present disclosure.

FIGS. 9A-9F conceptually illustrate different example techniques for adjusting the noise of various components in the ADC circuit of FIG. 7, in accordance with certain aspects of the present disclosure.

FIG. 10 is a flow diagram of example operations for running an ADC circuit, in accordance with certain aspects of the present disclosure.

### DETAILED DESCRIPTION

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein, one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example ADC Circuit with Redundancy

To meet certain resolution and/or bandwidth specifications of a system, multi-stage analog-to-digital converters (ADCs) may be employed. These multi-stage ADCs may be implemented using pipeline or successive approximation register (SAR) ADC structures, for example. Advantages of these ADC structures may be enhanced with the use of redundancy in some cases. Redundancy is the act of performing extra quantization steps on the input to an ADC stage, while maintaining the same overall ADC resolution. For example, SAR ADCs may be highly sensitive to temporary errors, such as settling errors of the digital-to-analog converter (DAC) or reference voltage. Redundancy may be used in multi-stage SAR ADC circuits to reduce the sensitivity to comparator offset, settling errors, and other intermediate errors. Certain aspects of the present disclosure may also utilize redundancy to help control the noise of the comparator.

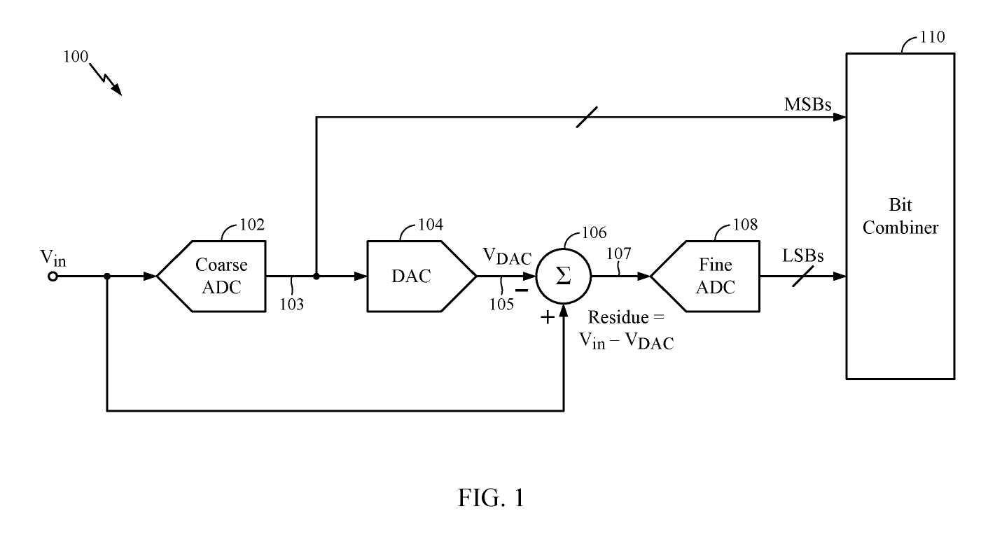

FIG. 1 is a block diagram of an example two-stage ADC circuit 100 with redundancy, in which aspects of the present disclosure may be practiced. FIG. 1 provides one example topology for an ADC circuit with redundancy; a person having ordinary skill in the art will understand that there are several other topologies for ADC circuits with redundancy, in which aspects of the present disclosure may be practiced. The ADC circuit 100 of FIG. 1 comprises a coarse ADC 102, a digital-to-analog converter (DAC) 104, a summer 106, a fine ADC 108, and a bit combiner 110. The coarse ADC 102 and the fine ADC 108 may be implemented with any suitable ADC, such as a SAR ADC. The coarse ADC 102 converts the analog voltage input signal (Vᵢₙ) to a digital signal and determines the most significant bits (MSBs) for the ADC circuit 100. The DAC 104 converts the digital output 103 of the coarse ADC 102 back to an analog signal (V_{DAC}). The summer 106 effectively computes the analog residue signal 107 by subtracting the output 105 of the DAC 104 from the analog input signal (Vᵢₙ−V_{DAC}). The fine ADC 108 converts the analog residue signal 107 to a digital signal, thereby determining the least significant bits (LSBs) for the ADC circuit 100. The bit combiner 110 combines the MSBs with the LSBs in the digital domain. In certain aspects, background noise estimation using a circular histogram noise figure (CHNF) may be performed for the ADC circuit 100, as described in more detail below.

### Example ADC Circuit Operations with Background Noise Estimation and Adjustment

During the design cycle of an analog-to-digital converter (ADC), comparator noise is typically designed with significant margin to meet the desired specifications for ADC noise. Comparator noise may be controlled in the corners by matching the comparator with auxiliary circuits that track process, voltage, and temperature (PVT). However, such PVT tracking circuits typically occupy a lot of area and involve considerable design effort. Furthermore, there is no distinction between the comparator noise and other noise sources existing in the ADC (e.g., thermal noise (i.e., kT/C noise) of the sampling or errors in preceding blocks). Traditionally, the noise of an ADC may be measured by applying a small input to the ADC and measuring the output noise in the lab. However, conventional ADC noise measurements cannot be done in the background and cannot be implemented on a chip. Some comparator architectures that are superior in speed and/or area are avoided because control of the noise of these alternative comparator architectures is not possible, is too complex, and/or is too costly.

Certain aspects of the present disclosure provide techniques and apparatus for determining the noise of an ADC circuit with redundancy using a circular histogram noise figure (CHNF). Such techniques allow for extraction of the power of the noise in the comparator of certain ADC circuits, which enables measuring the noise in the ADC circuit in the background, on chip. Furthermore, by measuring the noise, the noise of one or more components in the ADC circuit may be reduced on the fly, using feedback control.

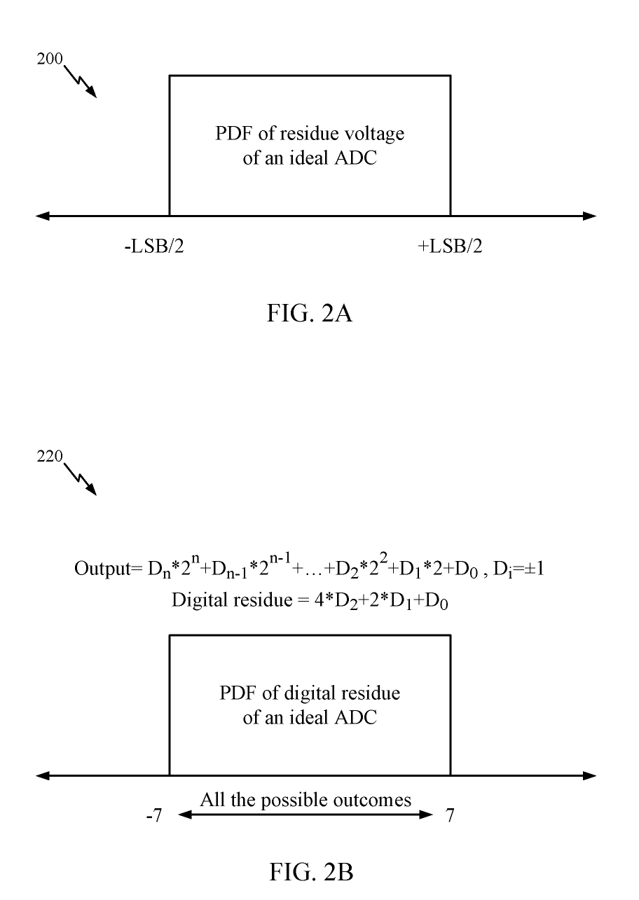

FIG. 2A illustrates an example probability density function (PDF) 200 of the analog residue at the last stage of an ideal multi-stage ADC with redundancy. In the PDF 200, all analog residue values ranging from one-half of a negative least significant bit (−LSB/2) to one-half of a positive LSB (+LSB/2) have an equal likelihood of being the residue value, leading to the window function for the PDF 200. Similarly, at any given stage of the same ideal multi-stage ADC, the digital residue can be considered as the last LSBs of the output word, as illustrated in the example PDF 220 of the digital residue in FIG. 2B. In the example PDF 220 for the last three LSBs, all digital residue values ranging from −7 to +7 have an equal likelihood of being the residue value of the ideal ADC.

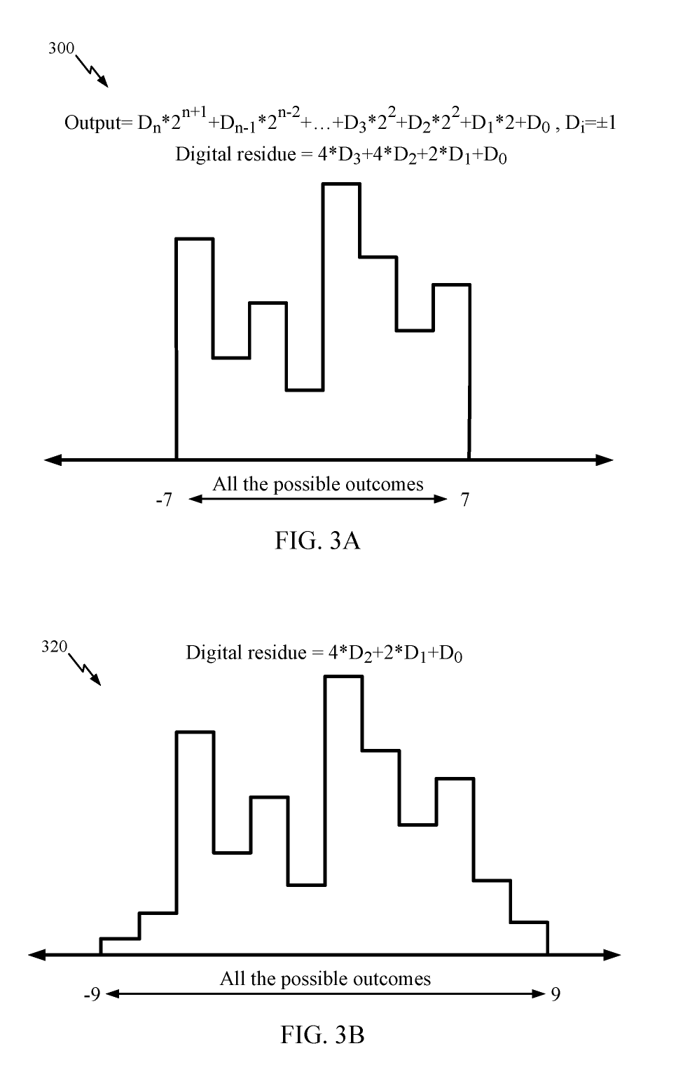

In ADCs with redundancy, by definition, the possible values for the residue after the redundancy stage are larger than the actual values that will be exercised. This will leave some slack for the stages before the redundancy stage to introduce some errors and still be fixed by redundancy. These errors shift the digital residue's PDF (or histogram estimating the PDF) away from the center; however, these errors do not change the code span of the residue's PDF (or histogram). To ensure that different shifts due to previous stages do not spread the histogram, the only codes that may be used in the generation of the histogram are those satisfying the condition in which the redundancy decision and the previous decision are opposite each other. The errors in the stages after the redundancy though change the shape of the PDF (or histogram). As shown in the example histogram 300 of FIG. 3A, for example, non-linearity deforms the ideal histogram block shape (e.g., the window function of the PDF 220) without spreading over more histogram bins (i.e., the residue codes stay within the range from −7 to +7 in this example). Noise, however, spreads the residue to a larger span of codes, as shown in the histogram 320 of FIG. 3B, where the residue codes range from −9 to +9.

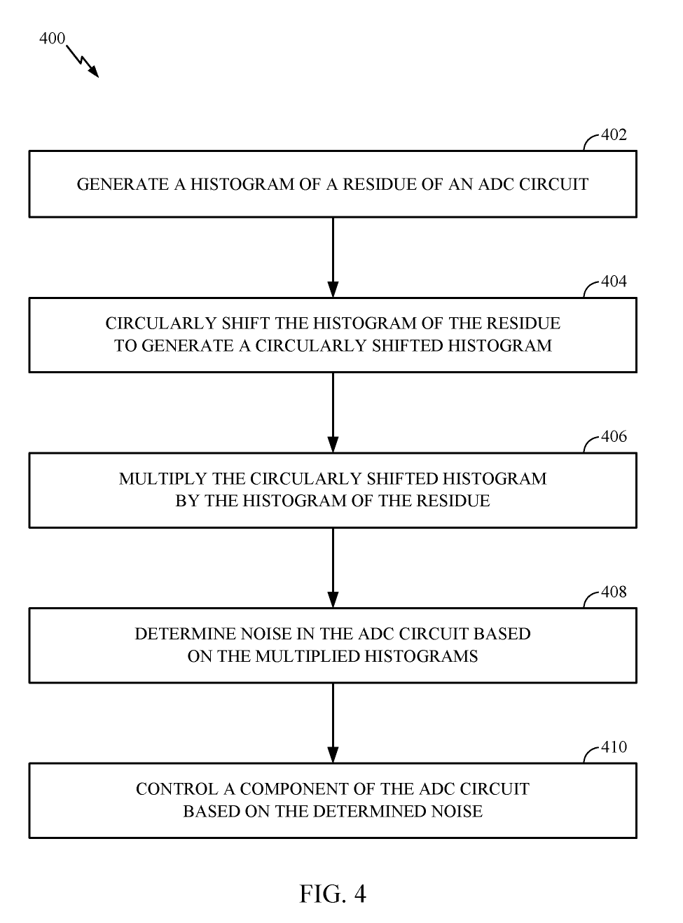

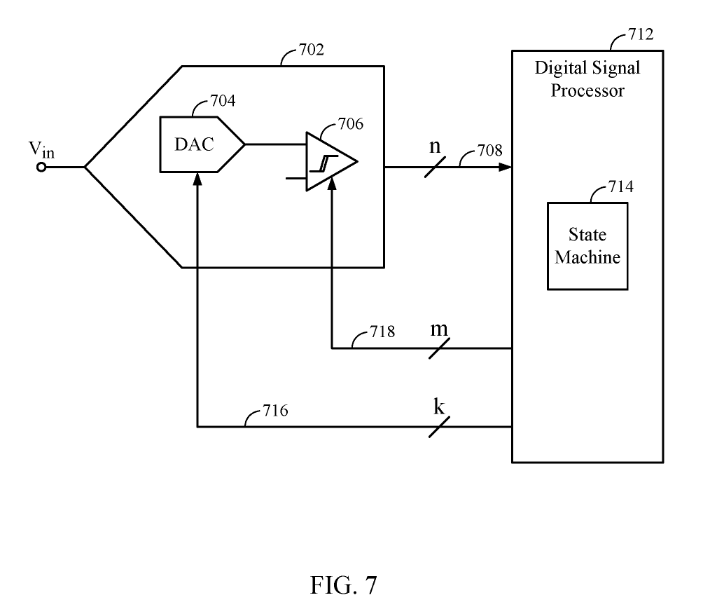

FIG. 4 is a flow diagram illustrating example operations 400 for running an ADC circuit, based on background noise estimation using a circular histogram noise figure (CHNF), in accordance with certain aspects of the present disclosure. The operations 400 may be performed for an ADC circuit with redundancy (e.g., the ADC circuit 702 of FIG. 7) and may be performed by at least one processor, such as a digital signal processor (DSP) or the digital circuitry 712 of FIG. 7, as described in detail below.

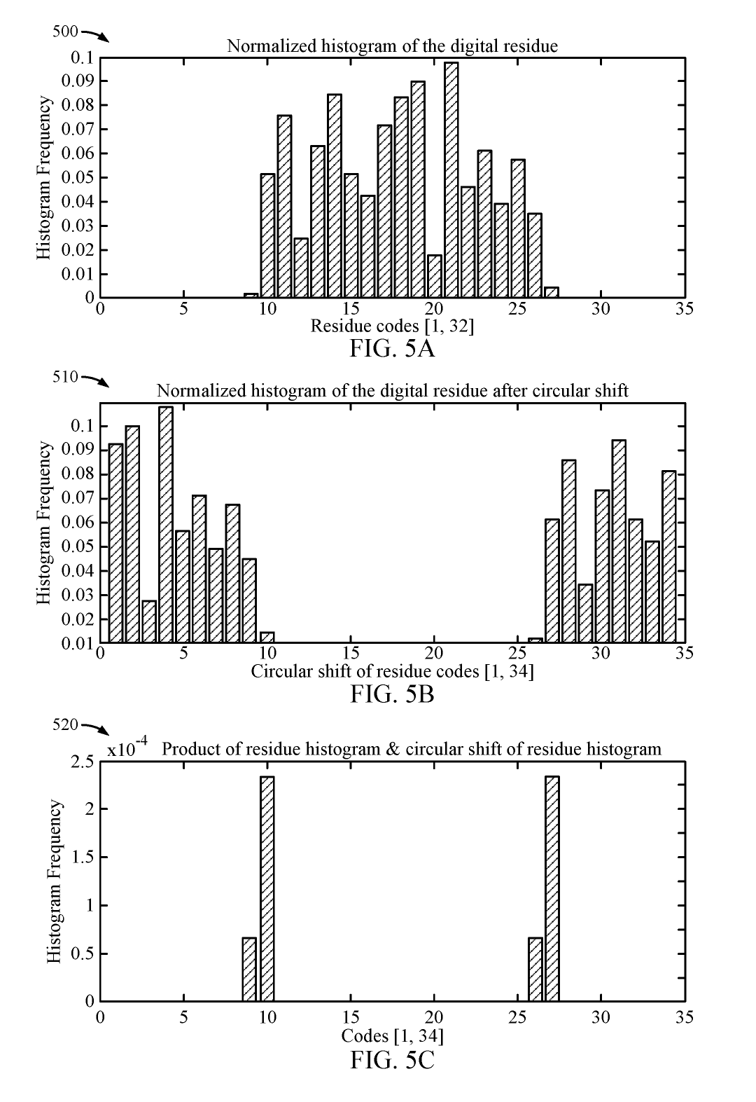

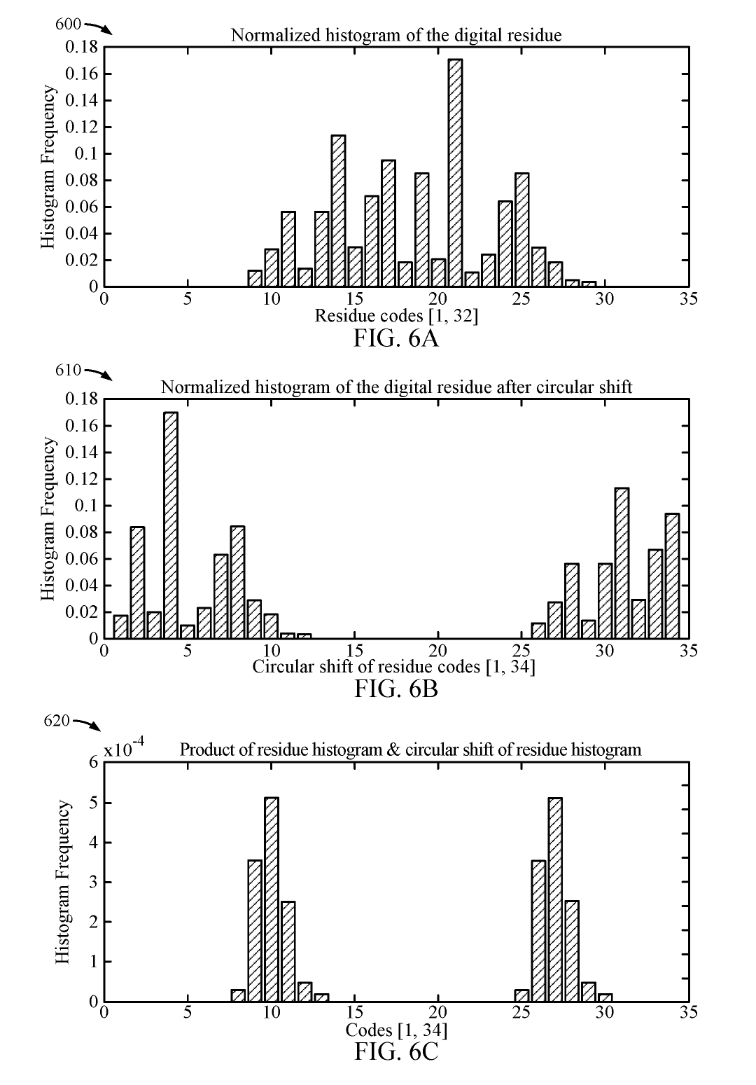

The operations 400 may begin, at block 402, with the processor generating a histogram of a residue of the ADC circuit. FIGS. 5A and 6A illustrate example normalized histograms 500 and 600, respectively. The bin width in these histograms 500 and 600 is one LSB (i.e., one code) of the ADC circuit, although any suitable bin width may be used. For example, the histogram bin width may be two LSBs or larger. Although accuracy of the noise calculation may suffer with larger histogram bin widths, the noise calculation may be processed faster. The residue codes in both example histograms 500 and 600 range from 1 to 32.

The operations 400 may continue, at block 404, with the processor circularly shifting the histogram of the residue to generate a circularly shifted histogram. The histogram of the residue may be shifted to the left or to the right. FIGS. 5B and 6B illustrate example circularly shifted histograms 510 and 610, respectively, after the histograms 500 and 600 are circularly shifted. To achieve circular shifting, the histogram of the residue may be shifted approximately one half of the residue code range, for example, to the left or to the right with wrap around. For some examples, shifting approximately one half of the residue code range may include shifting the histogram of the residue one more than one half of the residue, such that the residue code range is expanded by two in the circularly shifted histogram. For example, with a residue code range of 32 codes in the histograms 500 and 600, circularly shifting at block 404 includes shifting the histograms by 17 codes (1+32/2) to the right, such that the circularly shifted histograms 510 and 610 have a residue code range of 34 codes.

The operations 400 may continue, at block 406, with the processor multiplying the circularly shifted histogram by the histogram of the residue to generate a product. For example, the product 520 of multiplying the histogram 500 of FIG. 5A and the circularly shifted histogram 510 of FIG. 5B is illustrated in FIG. 5C. Likewise, the product 620 of multiplying the histogram 600 of FIG. 6A and the circularly shifted histogram 610 of FIG. 6B is illustrated in FIG. 6C.

At block 408, the processor may determine noise in the ADC circuit based on the multiplied histograms. According to certain aspects, the processor may determine the noise in the ADC circuit based on an area underneath the multiplied histograms, where this area is proportional to a power of the noise. For example, the area underneath the product 520 of FIG. 5C in the lower noise example may be 6e-4, whereas the area underneath the product 620 of FIG. 6C in the higher noise example may be 2.4e-3. This area may be referred to as the circular histogram noise figure (CHNF).

At block 410, a component of the ADC circuit may be controlled based on the noise determined at block 408. For certain aspects, the processor may output a control signal to control the component of the ADC circuit.

According to certain aspects, the ADC circuit is or includes a multi-stage ADC circuit with redundancy. In this case, a stage in the multi-stage ADC circuit comprises the component of the ADC circuit.

FIG. 7 is a block diagram of an example ADC circuit 702 and digital circuitry 712 supporting background noise estimation and control feedback for adjusting noise of various components in the ADC circuit, in accordance with certain aspects of the present disclosure. The ADC circuit 702 may be a multi-stage ADC circuit with redundancy, as described above. The ADC circuit 702 may be implemented using any of various suitable types of ADCs, such as pipeline or successive approximation register (SAR) ADCs. No matter which type of ADC is used, the ADC circuit 702 may include various components, such as at least one digital-to-analog converter (DAC) 704 and at least one comparator 706, with parameters that may be controlled to adjust noise of the ADC circuit 702. For certain aspects, each stage of the ADC circuit 702 may include a DAC 704 and a comparator 706. The DAC 704 and/or the comparator 706 may receive power from a power rail (e.g., Vdd) and may receive a clock signal for synchronous operation. The comparator 706 may include any of various suitable types of comparators, such as a Strong-Arm comparator, a multi-stage comparator, a current-mode logic (CML) comparator, a preamplifier-latch comparator, and the like.

The ADC circuit 702 may receive an analog input signal (Vin) and convert this signal to a digital output signal 708 having a number of bits (e.g., n bits as shown) for processing by the digital circuitry 712. This digital signal processing may include background noise estimation while the ADC circuit 702 is concurrently performing normal analog-to-digital conversion operations. The background noise estimation may include determining the circular histogram noise figure (CHNF) for the ADC circuit 702, for example, as described above with respect to blocks 402, 404, 406, and 408 of FIG. 4. The CHNF may be determined based on multiple samples of the residue signal (making up at least a portion of the digital output signal 708), with a sufficient number of samples to generate a representative histogram of the residue.

Based on the estimated noise, the digital circuitry 712 may also provide one or more digital feedback control signals 716, 718 for controlling one or more parameters of one or more components in the ADC circuit 702 in an effort to adjust the noise of the ADC circuit, as described above with respect to block 410 of FIG. 4. For example, the digital circuitry 712 may output the digital feedback control signal 718 having a number of bits (e.g., m bits as shown) for controlling one or more parameters of the comparator 706. These parameters may include any of various suitable parameters that may affect the noise of a comparator, such as a power supply voltage, a common-mode voltage, a load capacitance, a tail current, a time delay of clock signals between comparator stages, and the like. Although only one feedback control signal 718 for one comparator 706 is illustrated in FIG. 7, there may be multiple feedback control signals going to multiple comparators in the ADC circuit 702. Additionally or alternatively, the digital circuitry 712 may output the digital feedback control signal 716 having a number of bits (e.g., k bits as shown) for controlling one or more parameters of the DAC 704. These parameters may include any of various suitable parameters that may affect the noise of a DAC, such as a power supply voltage or a common-mode voltage. Although only one feedback control signal 716 for one DAC 704 is illustrated in FIG. 7, there may be multiple feedback control signals going to multiple DACs in the ADC circuit 702. A state machine 714 in the digital circuitry 712 may be used to determine the CHNF and/or provide the digital control feedback to control the noise of the ADC circuit 702.

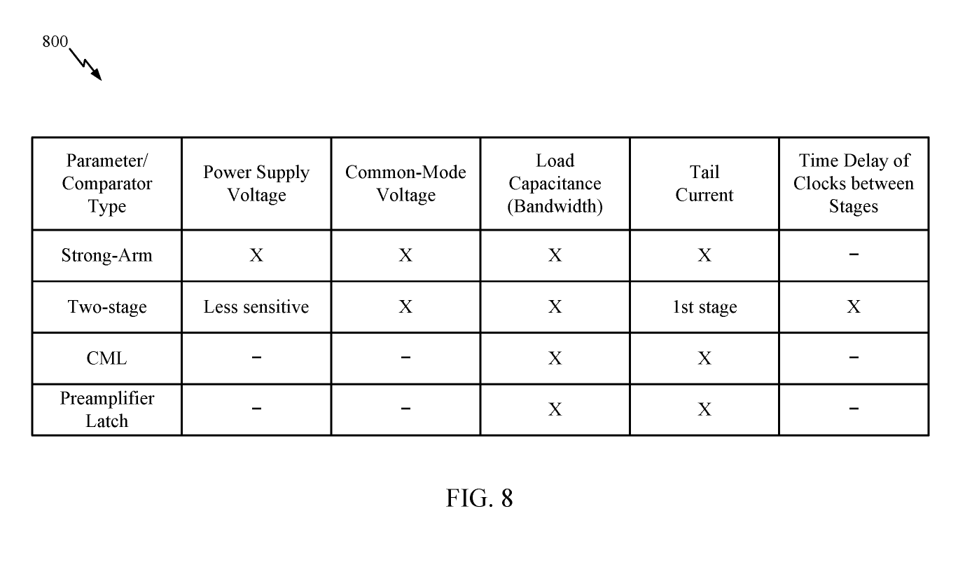

FIG. 8 is a table 800 comparing example comparator types with various ADC circuit parameters that may be controlled to adjust noise of the ADC circuit 702 of FIG. 7, in accordance with certain aspects of the present disclosure. The noise adjustment may be based, for example, on background noise estimation using a CHNF, as described above. The ADC circuit parameters may include a power supply voltage of the comparator, a common-mode voltage of the comparator, a load capacitance (or other characteristics that affect the bandwidth) of the comparator, a tail current of the comparator, or a time delay between clock signals routed to different stages of the comparator. For example, the noise of a Strong-Arm comparator may be adjusted by controlling the power-supply voltage, the common-mode voltage, the load capacitance, and/or the tail current. The noise of a two-stage comparator may be adjusted by controlling the common-mode voltage, the load capacitance, the tail current (e.g., of the first stage), and/or the time delay between clocks. The noise of the two-stage comparator may also be adjusted by controlling the power supply voltage, although to a lesser degree, and this adjustment may be less sensitive than for a Strong-Arm comparator, for example. The noise of a CML comparator or a preamplifier-latch comparator may be adjusted by controlling the load capacitance and/or the tail current.

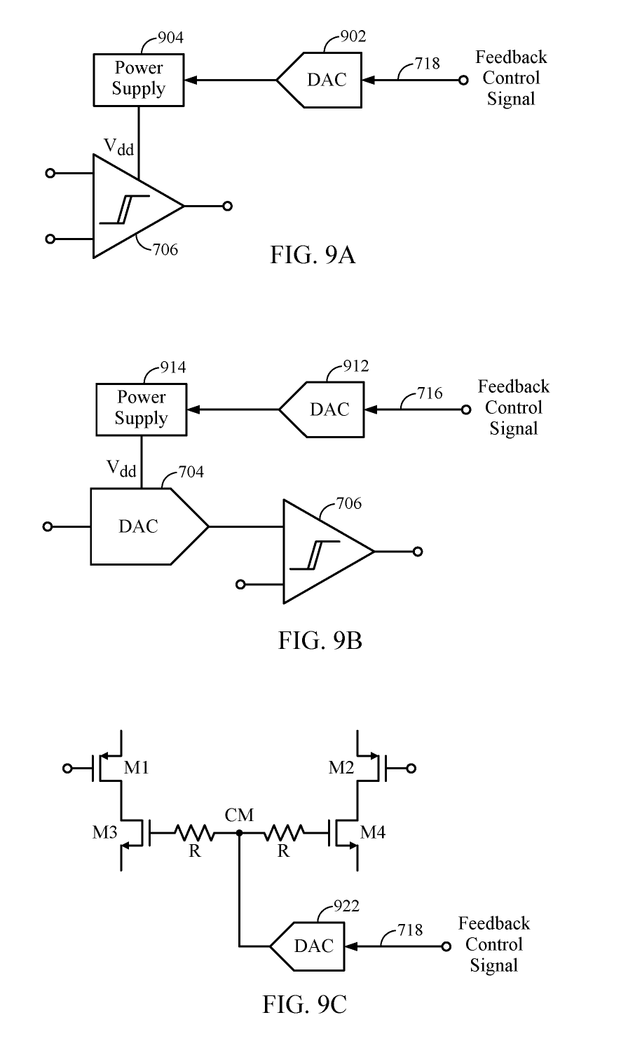

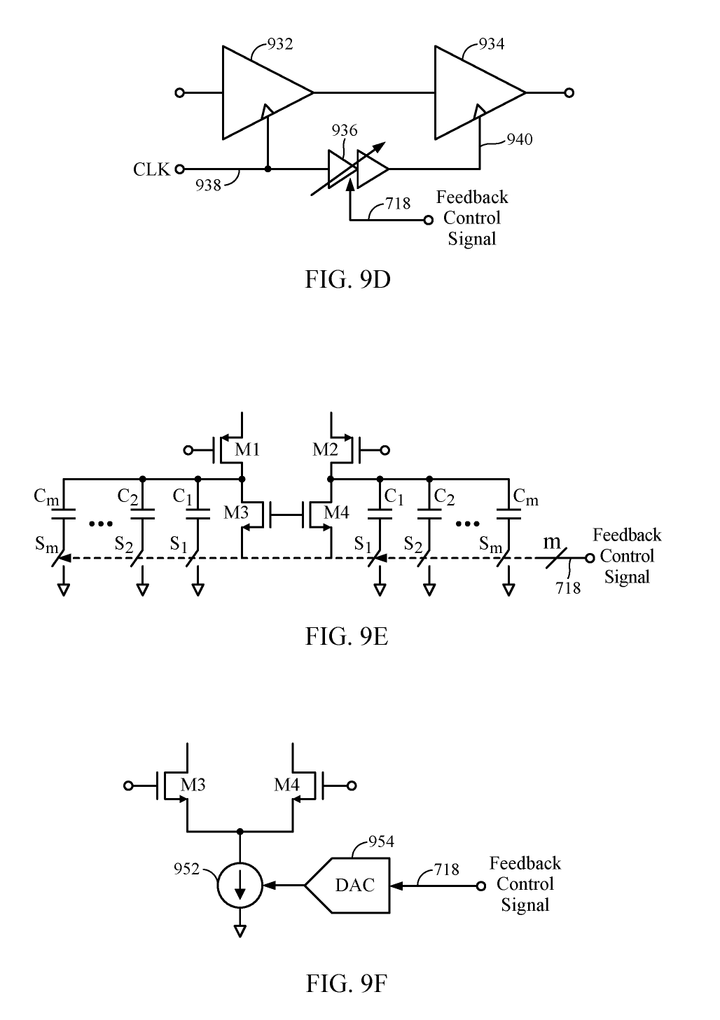

FIGS. 9A-9F conceptually illustrate different example techniques for adjusting the noise of various components in the ADC circuit of FIG. 7, in accordance with certain aspects of the present disclosure.

FIG. 9A conceptually illustrates adjusting the power-supply voltage (e.g., Vdd) of the comparator 706, in accordance with certain aspects of the present disclosure. In this example, a digital feedback control signal (e.g., control signal 718) may be supplied to a DAC 902 to convert the digital signal to an analog signal. The analog signal may be used to control an adjustable power supply 904 (e.g., a low dropout regulator (LDO)) providing the power-supply voltage. In this manner, the noise of the comparator 706 may be adjusted. For certain aspects, the adjustable power supply 904 may include an internal DAC. In this case, the digital feedback control signal may be provided directly to the adjustable power supply 904.

FIG. 9B conceptually illustrates adjusting the power-supply voltage (e.g., Vdd) of the DAC 704, in accordance with certain aspects of the present disclosure. In this example, a digital feedback control signal (e.g., control signal 716) may be supplied to a DAC 912 to convert the digital signal to an analog signal. The analog signal may be used to control an adjustable power supply 914 (e.g., an LDO) providing the power-supply voltage. In this manner, the noise of the DAC 704 may be adjusted. For certain aspects, the adjustable power supply 914 may include an internal DAC. In this case, the digital feedback control signal may be provided directly to the adjustable power supply 914.

According to certain aspects, the power-supply voltage for both the DAC 704 and the comparator 706 may be adjusted. For certain aspects, the power-supply voltage to both components may be adjusted using a single adjustable power supply for certain aspects. For other aspects, each of the DAC 704 and the comparator 706 may have its own adjustable power supply, combining the concepts illustrated in FIGS. 9A and 9B, for example.

FIG. 9C conceptually illustrates adjusting the common-mode voltage of an example comparator circuit, which may be included in the comparator 706, in accordance with certain aspects of the present disclosure. The comparator circuit may include a differential CMOS transistor circuit, which may include PMOS transistors M1 and M2 and NMOS transistors M3 and M4, for example. Other comparator circuit topologies may be used for this concept, as long as a means for controlling the common-mode voltage of the comparator is provided. In FIG. 9C, a digital feedback control signal (e.g., control signal 718) may be provided to a DAC 922 to convert the digital signal to an analog signal. The analog signal may be used to adjust the common-mode voltage of the comparator 706 by adjusting a voltage applied to a node between resistors R coupling the gates of transistors M3 and M4. By controlling the common-mode voltage of the comparator 706, the noise of the comparator may be adjusted for certain comparator types.

FIG. 9D conceptually illustrates adjusting the time delay of clock signals 938, 940 between two stages 932, 934 of a multi-stage comparator, which may compose the comparator 706, in accordance with certain aspects of the present disclosure. In this example, a digital feedback control signal (e.g., control signal 718) may be supplied to a programmable delay element 936 to control the delay between the clock signals 938, 940. By adjusting the delay, the noise of the comparator 706 may be adjusted for certain comparator types.

FIG. 9E conceptually illustrates adjusting the load capacitance (and the bandwidth) of the comparator 706, in accordance with certain aspects of the present disclosure. The comparator circuit may include a differential CMOS transistor circuit, which may include PMOS transistors M1 and M2 and NMOS transistors M3 and M4, for example. Other comparator circuit topologies may be used for this concept, as long as a means for controlling the bandwidth of the comparator is provided. In FIG. 9E, a digital feedback control signal (e.g., control signal 718) may be provided to a pair of circuits with tunable capacitance. Such circuits may be implemented, for example, with varactors or, as shown in FIG. 9E, by a switched-capacitor array. For example, for a feedback control signal with m bits, each switched-capacitor array may include m branches where each branch includes a capacitive element (labeled C₁ to Cₘ) in series with a switch (labeled S₁ to Sₘ). The switches are controlled by the feedback control signal to selectively close each of the switches, thereby controlling the load capacitance. In this manner, the noise of the comparator 706 may be adjusted.

FIG. 9F conceptually illustrates adjusting the tail current of an example comparator circuit, which may be included in the comparator 706, in accordance with certain aspects of the present disclosure. The comparator circuit may include a differential transistor pair, such as NMOS transistors M3 and M4, for example. Other comparator circuit topologies may be used for this concept, as long as a means for controlling the tail current of the comparator is provided. In FIG. 9F, a digital feedback control signal (e.g., control signal 718) may be provided to a DAC 954 to convert the digital signal to an analog signal. The analog signal may be used to adjust the tail current of the comparator 706 by adjusting a tuning voltage applied to an adjustable current sink 952 coupled to the sources of transistors M3 and M4. By controlling the tail current of the comparator 706, the noise of the comparator may be adjusted for certain comparator types.

Returning to FIG. 4, according to certain aspects, the controlling at block 410 involves outputting a digital control signal based on the determined noise, converting the digital control signal to an analog control signal with a digital-to-analog converter (DAC) and adjusting a variable circuit using the analog control signal. For certain aspects, the component comprises a comparator (e.g., a Strong-Arm comparator, a multi-stage comparator, a current-mode logic (CML) comparator). In this case, adjusting the variable circuit includes at least one of adjusting a common-mode voltage of the comparator, adjusting a power supply voltage for the comparator; adjusting a tail current of the comparator; or adjusting a load capacitance of the comparator. For certain aspects, the component comprises a DAC. In this case, adjusting the variable circuit may include at least one of adjusting a common-mode voltage of the DAC or adjusting a power supply voltage for the DAC.

According to certain aspects, the component comprises a current-mode logic (CML) comparator. In this case, the controlling at block 410 may entail at least one of adjusting a tail current of the CML comparator or adjusting a load capacitance of the CML comparator.

According to certain aspects, the component comprises a multi-stage comparator. In this case, the controlling at block 410 may involve adjusting a delay between two stages of the multi-stage comparator.

According to certain aspects, the operations 400 may further include the ADC circuit converting an analog input signal to a digital output signal. In this case, the generating at block 402, the circularly shifting at block 404, the multiplying at block 406, the determining at block 408, and the controlling at block 410 may occur continuously and concurrently with the converting (e.g., in the background).

Any number of suitable samples of the residue may be used to generate the histogram of the residue at block 402. The number of samples may have a bandwidth-noise tradeoff. For certain aspects, the generating at block 402 involves using one million samples of the residue to generate the histogram of the residue.

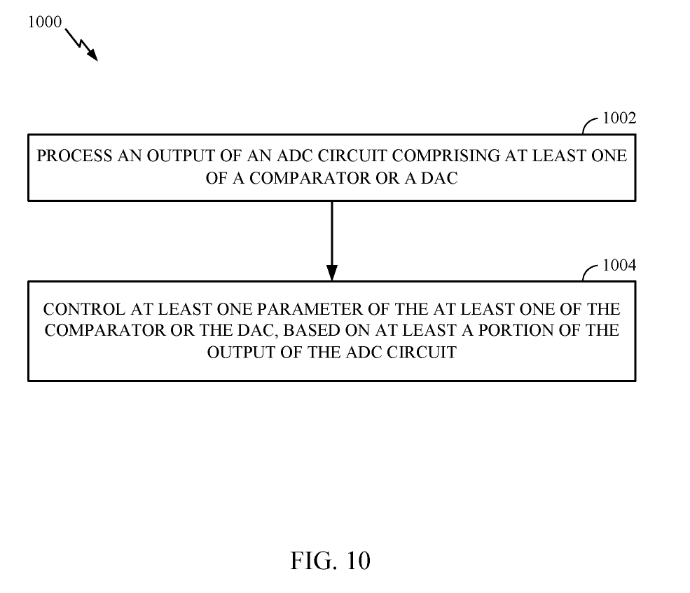

FIG. 10 is a flow diagram illustrating example operations 1000 for running an ADC circuit, in accordance with certain aspects of the present disclosure. The operations 1000 may be performed for an ADC circuit with redundancy (e.g., the ADC circuit 702 of FIG. 7) and may be performed by at least one processor, such as a digital signal processor (DSP) or the digital circuitry 712 of FIG. 7.

The operations 1000 may begin, at block 1002, with the processor processing an output (e.g., digital output signal 708) of the ADC circuit. The ADC circuit may include at least one of a comparator or a DAC. At block 1004, the processor may control at least one parameter of the at least one of the comparator or the DAC, based on at least a portion (e.g., a residue) of the output of the ADC circuit.

According to certain aspects, the at least the portion of the output of the ADC circuit comprises a residue of the ADC circuit. For certain aspects, the processing at block 1002 involves generating a histogram of the residue of the ADC circuit, circularly shifting the histogram of the residue to generate a circularly shifted histogram, multiplying the circularly shifted histogram by the histogram of the residue, and determining noise in the ADC circuit based on the multiplied histograms. In this case, the controlling at block 1004 may entail controlling the at least one parameter of the at least one of the comparator or the DAC based on the determined noise.

Certain aspects of the present disclosure provide an ADC circuit. The ADC circuit generally includes at least one of a comparator or a DAC and at least one digital feedback input. The at least one digital feedback input is coupled to the at least one of the comparator or the DAC and is configured to adjust at least one parameter of the at least one of the comparator or the DAC based on at least a portion of an output of the ADC circuit.

According to certain aspects, the at least one digital feedback input is configured to adjust the at least one parameter of the at least one of the comparator or the DAC based on noise of the at least the portion of the output of the ADC circuit. For certain aspects, the ADC circuit includes or is a multi-stage ADC circuit with redundancy. In this case, the noise of the at least the portion of the output of the ADC circuit may be based on a residue of a first stage in the multi-stage ADC circuit. For certain aspects, a second stage in the multi-stage ADC circuit includes the at least one of the comparator or the DAC. For certain aspects, the multi-stage ADC circuit is or includes a multi-stage successive approximation register (SAR) ADC circuit. For certain aspects, the first stage is the same stage as the second stage.

According to certain aspects, the at least one parameter includes at least one of a power supply voltage, a common-mode voltage, a load capacitance, or a tail current, of the at least one of the comparator or the DAC.

According to certain aspects, the ADC circuit further includes another DAC. In this case, the other DAC may have an input coupled to the at least one digital feedback input and may have an output coupled to a variable circuit of the at least one of the comparator or the DAC. For certain aspects, the other DAC is configured to convert a digital control signal of the at least one digital feedback input to an analog control signal to adjust the variable circuit. In this case, the variable circuit may include an adjustable power supply, a common-mode tuning circuit, a programmable capacitance circuit, or an adjustable current source, for example.

According to certain aspects, the at least one of the comparator or the DAC is or includes a multi-stage comparator. In this case, the at least one parameter may include a delay between two stages of the multi-stage comparator.

According to certain aspects, the at least one of the comparator or the DAC is or includes a Strong-Arm comparator.

The various operations of methods described above may be performed by any suitable means capable of performing the corresponding functions. The means may include various hardware component(s) and/or module(s), including, but not limited to one or more circuits. Generally, where there are operations illustrated in figures, those operations may have corresponding counterpart means-plus-function components with similar numbering.

For example, means for comparing may include a comparator, such as the comparator 706 as illustrated in FIG. 7. Means for digital-to-analog converting may include a DAC, such as the DAC 704 as shown in FIG. 7. Means for adjusting may include a DAC (e.g., DAC 902, 912, 922, or 954 as depicted in FIGS. 9A-9C and 9F) and/or a variable circuit, such as an adjustable power supply (e.g., the adjustable power supply 904 or 914 as illustrated in FIGS. 9A and 9B), a common-mode tuning circuit (e.g., the resistors R as shown in FIG. 9C), a programmable capacitance circuit (e.g., one or more varactors and/or a switched-capacitor array, such as that shown in FIG. 9E) or an adjustable current source (e.g., the adjustable current sink 952 as portrayed in FIG. 9F).

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The various illustrative logical blocks, modules, and circuits described in connection with the present disclosure may be implemented or performed with discrete hardware components designed to perform the functions described herein.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes and variations may be made in the arrangement, operation and details of the methods and apparatus described above without departing from the scope of the claims.

What is claimed is:

1. An analog-to-digital converter (ADC) circuit comprising:
at least one of a comparator or a digital-to-analog converter (DAC); and
at least one digital feedback input coupled to the at least one of the comparator or the DAC and configured to adjust at least one parameter of the at least one of the comparator or the DAC based on at least a portion of an output of the ADC circuit.

2. The ADC circuit of claim 1, wherein the at least one digital feedback input is configured to adjust the at least one parameter of the at least one of the comparator or the DAC based on noise of the at least the portion of the output of the ADC circuit.

3. The ADC circuit of claim 2, wherein the ADC circuit comprises a multi-stage ADC circuit with redundancy, wherein the noise of the at least the portion of the output of the ADC circuit is based on a residue of a first stage in the multi-stage ADC circuit, and wherein a second stage in the multi-stage ADC circuit comprises the at least one of the comparator or the DAC.

4. The ADC circuit of claim 3, wherein the multi-stage ADC circuit comprises a multi-stage successive approximation register (SAR) ADC circuit.

5. The ADC circuit of claim 3, wherein the first stage is a same stage as the second stage.

6. The ADC circuit of claim 1, wherein the at least one parameter comprises at least one of a power supply voltage, a common-mode voltage, a load capacitance, or a tail current, of the at least one of the comparator or the DAC.

7. The ADC circuit of claim 1, further comprising another DAC having an input coupled to the at least one digital feedback input and having an output coupled to a variable circuit of the at least one of the comparator or the DAC, wherein the other DAC is configured to convert a digital control signal of the at least one digital feedback input to an analog control signal to adjust the variable circuit.

8. The ADC circuit of claim 7, wherein the variable circuit comprises an adjustable power supply, a common-mode tuning circuit, a programmable capacitance circuit, or an adjustable current source.

9. The ADC circuit of claim 1, wherein the at least one of the comparator or the DAC comprises a multi-stage comparator and wherein the at least one parameter comprises a delay between two stages of the multi-stage comparator.

10. The ADC circuit of claim 1, wherein the at least one of the comparator or the DAC comprises a Strong-Arm comparator.

11. A method of operating an analog-to-digital converter (ADC) circuit, comprising:
processing an output of the ADC circuit, the ADC circuit comprising at least one of a comparator or a digital-to-analog converter (DAC); and
controlling at least one parameter of the at least one of the comparator or the DAC, based on at least a portion of the output of the ADC circuit.

12. The method of claim 11, wherein the ADC circuit comprises a multi-stage ADC circuit with redundancy and wherein a stage in the multi-stage ADC circuit comprises the at least one of the comparator or the DAC.

13. The method of claim 11, wherein the at least the portion of the output of the ADC circuit comprises a residue of the ADC circuit and wherein the processing comprises:
generating a histogram of the residue of the ADC circuit;
circularly shifting the histogram of the residue to generate a circularly shifted histogram;
multiplying the circularly shifted histogram by the histogram of the residue; and
determining noise in the ADC circuit based on the multiplied histograms, wherein the controlling comprises controlling the at least one parameter of the at least one of the comparator or the DAC based on the determined noise.

14. The method of claim 13, wherein the determining comprises determining the noise in the ADC circuit based on an area underneath the multiplied histograms, the area being proportional to a power of the noise.

15. The method of claim 13, further comprising converting an analog input signal to a digital output signal with the ADC circuit, wherein the generating, the circularly shifting, the multiplying, the determining, and the controlling occur continuously and concurrently with the converting.

16. The method of claim 13, wherein a bin width for the histogram of the residue is equal to a least significant bit (LSB) of the ADC circuit.

17. The method of claim 11, wherein the controlling comprises:
outputting a digital control signal based on the at least the portion of the output of the ADC circuit;
converting the digital control signal to an analog control signal; and
adjusting a variable circuit using the analog control signal.

18. The method of claim 17, wherein adjusting the variable circuit comprises at least one of:
adjusting a common-mode voltage of the comparator;
adjusting a power supply voltage for the comparator;
adjusting a tail current of the comparator; or
adjusting a load capacitance of the comparator.

19. The method of claim 17, wherein adjusting the variable circuit comprises at least one of:
adjusting a common-mode voltage of the DAC; or
adjusting a power supply voltage for the DAC.

20. The method of claim 11, wherein the at least one of the comparator or the DAC comprises a current-mode logic (CML) comparator and wherein the controlling comprises at least one of:
controlling a tail current of the CML comparator; or
controlling a load capacitance of the CML comparator.

21. The method of claim 11, wherein the at least one of the comparator or the DAC comprises a multi-stage comparator and wherein the controlling comprises controlling a delay between two stages of the multi-stage comparator.

22. The method of claim 11, wherein the at least one parameter comprises at least one of a power supply voltage, a common-mode voltage, a load capacitance, or a tail current, of the at least one of the comparator or the DAC.

23. An apparatus for converting an analog signal to a digital signal, the apparatus comprising:
at least one of a comparator or a digital-to-analog converter (DAC); and
means for adjusting at least one parameter of the at least one of the comparator or the DAC, based on at least a portion of an output of the apparatus.

24. The apparatus of claim 23, wherein the means for adjusting is configured to adjust the at least one parameter of the at least one of the comparator or the DAC, based on noise of the at least the portion of the output of the apparatus.

25. The apparatus of claim 24, wherein the apparatus comprises a multi-stage ADC circuit with redundancy, wherein the noise of the at least the portion of the output of the apparatus is based on a residue of a first stage in the multi-stage ADC circuit, and wherein a second stage in the multi-stage ADC circuit comprises the at least one of the comparator or the DAC.

26. The apparatus of claim 25, wherein the first stage is a same stage as the second stage.

27. The apparatus of claim 23, wherein the at least one parameter comprises at least one of a power supply voltage, a common-mode voltage, a load capacitance, or a tail current, of the at least one of the comparator or the DAC.

28. The apparatus of claim 23, wherein the at least one of the comparator or the DAC comprises a multi-stage comparator and wherein the at least one parameter comprises a delay between two stages of the multi-stage comparator.
